(19) United States
(12) Patent Application Publication
(10) Pub. No.: US 2008/0135093 A1
(43) Pub. Date: Jun. 12, 2008

(54) Optoelectronic Device

(76) Inventor: David Yen, Burnaby (CA)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 11/761,570

(22) Filed: Jun. 12, 2007

(30) Foreign Application Priority Data
Jun. 12, 2006 (CN) 200610091328.4

(51) Int. Cl. H01L 31/04

(52) U.S. Cl. 136/259

(57) ABSTRACT

The optoelectronic apparatus of the present invention includes a solar cell and a prism located over the solar cell. The light reflected by the solar cell is reflected back to the solar cell by the prism. Therefore, the light repeatedly illuminates the solar cell to improve the power transference rate.

### RELATED APPLICATIONS

This application claims priority to China Application Serial Number 200610091328.4, filed Jun. 12, 2006, which is herein incorporated by reference.

### FIELD OF THE INVENTION

The present invention describes a power energy device, and more particularly, describes a solar power energy device.

### BACKGROUND OF THE INVENTION

Solar power energy is free power. In the past, expensive chips limited the application of solar power energy. However, solar power energy has become the most important alternative energy source today.

Typically, solar power is transformed into electrical power by a solar cell. The electrical power generated by a solar cell with an area of 1 m² is about 110 W/m². That is a 9 m² solar cell is required to generate 1 KW of electrical power. For a solar cell, the power transference rate is related to the illumination of the sun. In other words, the power transference rate on a sunny day is larger than the power transference rate on a cloudy day.

Therefore, the power transference rate must be enhanced.

### SUMMARY OF THE INVENTION

The main purpose of the present invention is to provide an optoelectronic apparatus that may enhance the power transference rate.

Accordingly, the optoelectronic apparatus of the present invention includes a solar cell and a prism located over the solar cell. The surface of the prism is a micro lens structure. The light reflected by the solar cell is reflected back to the solar cell by the micro lens structure. Therefore, according to the present invention, the light repeatedly illuminates the solar cell to improve the power transference rate.

In an embodiment, a “V” type with an interior 90 degree angle trench is used to form the micro lens structure.

The optoelectronic apparatus of the present invention has the following advantages. Light passing through the micro lens structure of the prism repeatedly illuminates the solar cell to improve the power transference rate.

### BRIEF DESCRIPTION OF THE DRAWINGS

The foregoing aspects and many of the attendant advantages of this invention will become more readily appreciated and better understood by referencing the following detailed description, when taken in conjunction with the accompanying drawings, wherein:

FIG. 1 illustrates a schematic diagram of an optoelectronic apparatus according to the present invention.

FIG. 2 illustrates a three-dimensional schematic diagram of a prism according to the present invention.

FIG. 3 illustrates a cross section schematic diagram of a prism according to the present invention.

FIG. 4 illustrates a cross section schematic diagram of two cross prisms according to the present invention.

### DETAILED DESCRIPTION OF THE PREFERRED EMBODIMENT

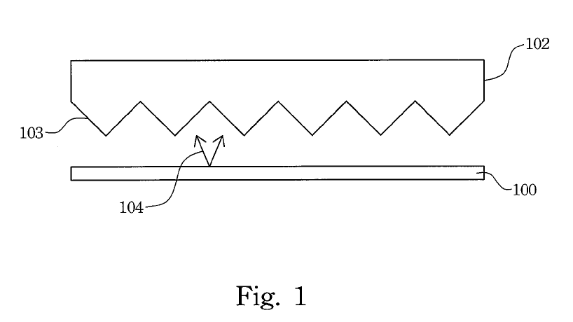

FIG. 1 illustrates a schematic diagram of an optoelectronic apparatus according to the present invention. The present invention includes a solar cell 100 and a prism 102 located over the solar cell 100 to improve the light usage. The surface of the prism 102 is a micro lens structure 103. The micro lens structure 103 reflects light back to initially reflected by the solar cell 100 back to the solar cell 100. Therefore, according to the present invention, the light repeatedly illuminates the solar cell 100 to improve the power transference rate.

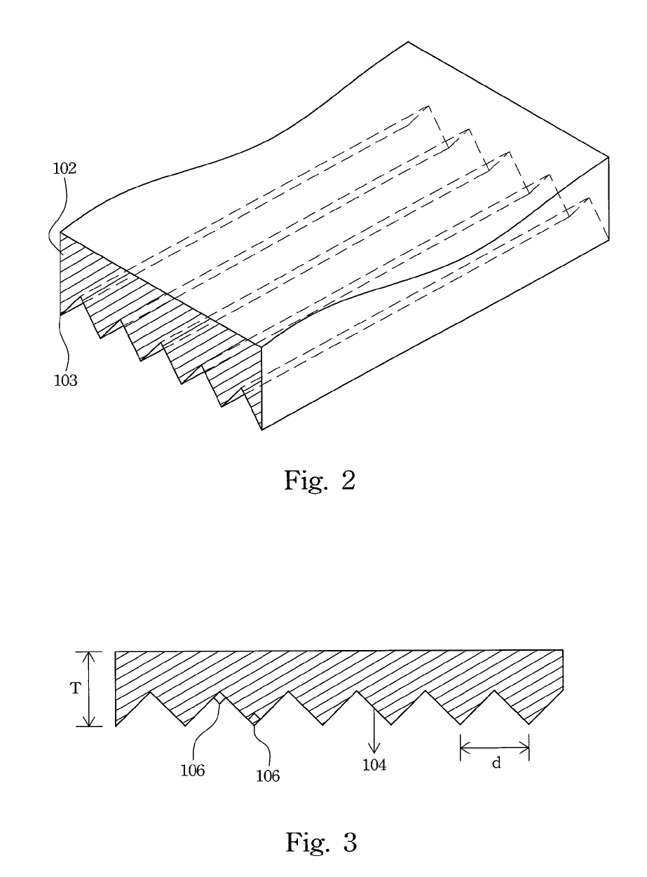

FIG. 2 illustrates a three-dimensional schematic diagram of a prism according to the present invention. In this embodiment, a “V” type trench with an interior angle of 90 degrees is used to form the micro lens structure 103. In another embodiment, a trench with another shape, such as a semicircle shape, may also be used in the present invention. According to this embodiment, the cross section of a prism unit of the micro lens structure 103 is a triangle. In an embodiment, as shown in the FIG. 3, the interior angle 106 is 90 degree. The thickness T of the prism is about 140˜250 um. A plurality of prism units is arranged in parallel to form the micro lens structure. The distance d between two adjacent prism units is about 20˜100 um. The 90 degree interior angle 106 totally reflects the light 104 reflected by the solar cell 100 back to the solar cell 100. Therefore, the light repeatedly illuminates the solar cell 100 to improve the power transference rate.

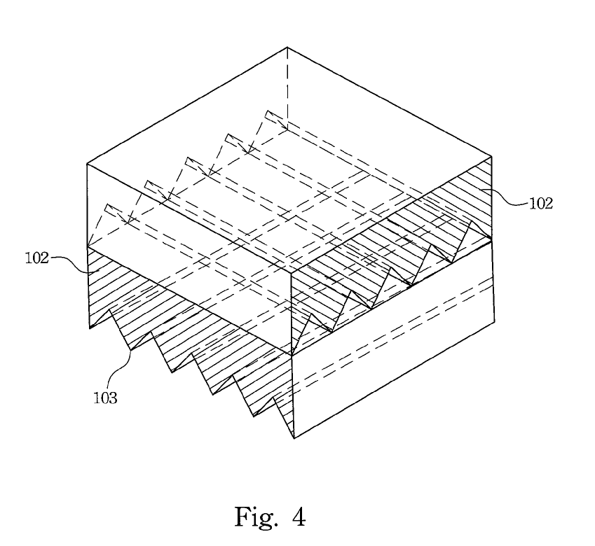

On the other hand, according to another embodiment, two cross prisms 102 may also be used in the present invention as shown in the FIG. 4. The two prisms cross each other. Therefore, the light 104 reflected by the solar cell 100 is further reflected back to the solar cell 100. Therefore, in this embodiment, the light loss is further reduced

Accordingly, a prism is located over the solar cell in the present invention. The light reflected by the solar cell is reflected back to the solar cell by the prism. Therefore, the light repeatedly illuminates the solar cell and improves the power transference rate.

As is understood by a person skilled in the art, the foregoing descriptions of the preferred embodiment of the present invention are an illustration of the present invention rather than a limitation thereof. Various modifications and similar arrangements are included within the spirit and scope of the appended claims. The scope of the claims should be accorded to the broadest interpretation so as to encompass all such modifications and similar structures. While a preferred embodiment of the invention has been illustrated and described, it will be appreciated that various changes can be made therein without departing from the spirit and scope of the invention.

What is claimed is:

1. An optoelectronic apparatus, comprising:
a solar cell; and
a light enhanced device located over the solar cell, wherein the light enhanced device has a micro structure facing the solar cell to reflect the light reflected from the solar cell back to the solar cell

2. The apparatus according to claim 1, wherein the light enhancing device is a prism.

3. The apparatus according to claim 1, wherein the light enhancing devices are two prisms that cross each other.

4. The apparatus according to claim 1, wherein a plurality of micro prisms are arranged in parallel to form the micro structure.

5. The apparatus according to claim 4, wherein an interior angle of each micro prism is 90 degrees.

6. The apparatus according to claim 4, wherein a distance between two adjacent micro prisms is 20˜100 um.

7. An optoelectronic apparatus, comprising:
a solar cell; and
two prisms crossing each other located over the solar cell, wherein each prism has a micro structure toward the solar cell to reflect the light reflected from the solar cell back to the solar cell, wherein a plurality of micro prisms are arranged in parallel to form the micro structure and the interior angle of each micro prism is 90 degrees.

8. The apparatus according to claim 7, wherein the distance between two adjacent micro prisms is 20˜100 um.
